(19) United States
(12) Patent Application Publication
(10) Pub. No.: US 2006/0045663 A1
(43) Pub. Date: Mar. 2, 2006

(54) Load port with manual FOUP door opening mechanism

(76) Inventors: Ravinder Aggarwal, Gilbert, AZ (US); James Kusbel, Scottsdale, AZ (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/912,299

(22) Filed: Aug. 5, 2004

(51) Int. Cl. H01L 21/677

(52) U.S. Cl. 414/217

(57) ABSTRACT

A load port comprises a platform for receiving a FOUP. The platform includes features for manually removing a FOUP door. The platform also includes features for placing the FOUP in operative relation to a wafer transfer robot configured to transfer wafers between first and second containers.

### BACKGROUND

1. Field of the Invention

The invention relates in general to the field of semiconductor processing equipment, and specifically to a load port for transferring wafers to or from a FOUP, the port having a manual FOUP door opening mechanism.

2. Description of the Related Art

In the semiconductor manufacturing industry, wafers are often stored and transported in sealable containers called front opening unified pods (FOUPs). It is often desirable or necessary to transfer wafers from one FOUP to another, or from a FOUP to a cassette, or from a shipping box to a FOUP, etc. These transfer processes are typically performed in a controlled environment, and are typically performed by wafer handling robots utilizing load ports for loading a FOUP into operative relationship with the robot. Presently available load ports utilize an automatic FOUP door opening mechanism, as described for example in U.S. patent application publication No. 2002/00699333 A1. These automated load ports are generally quite expensive, and in the case of an environment in which the volume of wafers to be transferred is relatively low, such load ports may be prohibitively expensive.

Notwithstanding the particular advantages of these automated FOUP opening load ports, there remains a need for a wafer transferring load port which is less expensive, but which adequately performs the transferring process.

### SUMMARY

In one embodiment, a method of transferring semiconductor wafers from a first container to a second container is provided. This embodiment comprises providing first and second containers, at least one of the containers having a plurality of wafers removably supported therein. The method also includes providing a wafer transfer robot having at least one load port which is configured to allow at least one of the containers to translate linearly, and to rotate. The method further includes placing a first container on the load port, manually removing a door of the first container, rotating the first container until an opening in the container is in a position to allow the robot to transfer wafers through the opening, and sealably locking the container to the load port.

According to another embodiment, an apparatus for transferring wafers between a first container and a second container comprises first and second supports for supporting the first and second containers. At least one of the supports is configured to allow a container to be rotatable and linearly translatable thereon. The apparatus further includes a mechanism for manually removing a door of at least one of the containers. The mechanism is mounted in proximity to at least one of the platforms. The apparatus also includes a wafer transfer robot configured to transfer wafers in a controlled environment between the first and second containers.

Still another embodiment teaches a method comprising providing first and second containers, each with a removable door, and at least one of the containers having a plurality of wafers removably supported therein. The method further includes providing a wafer transfer robot with a load port having a platform. The platform is configured to allow at least one of the containers to translate linearly and to rotate thereon. The method further includes providing a mechanism for manually removing a door of one of the containers. The mechanism is integrally mounted to the door of the housing. The method also includes placing a first container on the platform, engaging the door removal mechanism with the container door, and manually removing the door of the first container. Once the container door has been removed, the container is displaced toward the load port opening, and sealably locked to the opening in the load port such that wafers may be transferred through the opening. Additionally, the method includes exchanging wafers between first and second containers.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the present invention herein disclosed. These and other embodiments of the present invention will become readily apparent to those skilled in the art from the following detailed description of the preferred embodiments having reference to the attached figures, the invention not being limited to any particular preferred embodiment(s) disclosed.

### BRIEF DESCRIPTION OF DRAWINGS

Having thus summarized the general nature of the invention, certain preferred embodiments and modifications thereof will become apparent to those skilled in the art from the detailed description herein having reference to the figures that follow, of which:

FIG. 1 is a perspective view of a front opening unified pod (FOUP) with a door removed;

FIG. 2 is a front elevation view of a FOUP with a door attached;

FIG. 3A is a perspective view of a load port with a FOUP thereon with a load port door in an open position;

FIG. 3B is a perspective view of a load port with a FOUP thereon with a load port door in a closed position;

FIG. 4A-E are schematic illustrations of an exemplary path for a FOUP on a load port with a manual door removal mechanism; and

FIG. 5 is a perspective view of an alternative embodiment of a load port.

### DETAILED DESCRIPTION

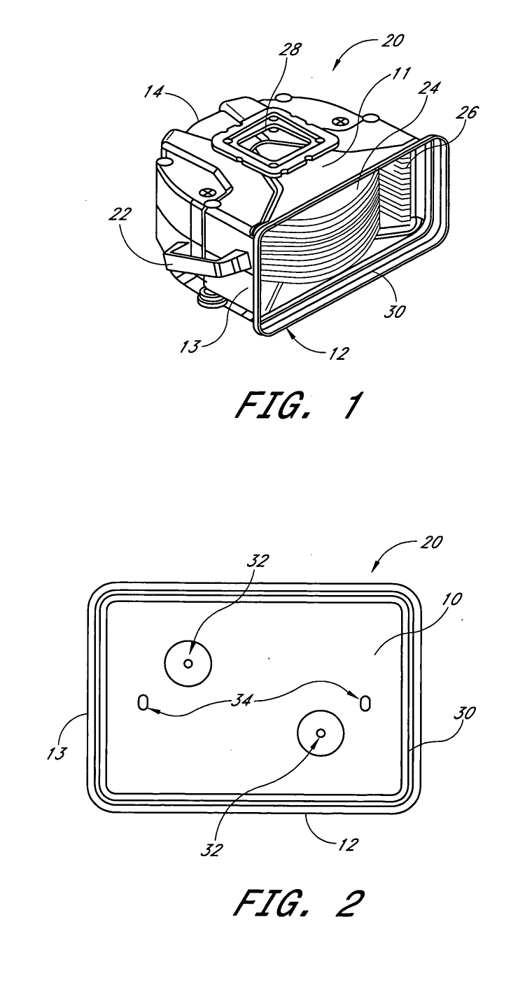

A method and apparatus for transferring wafers between first and second containers will now be described with reference to FIGS. 1-4E. The method and apparatus described have the particular advantage that they are substantially less costly to manufacture than previous fully automatic methods and apparatus.

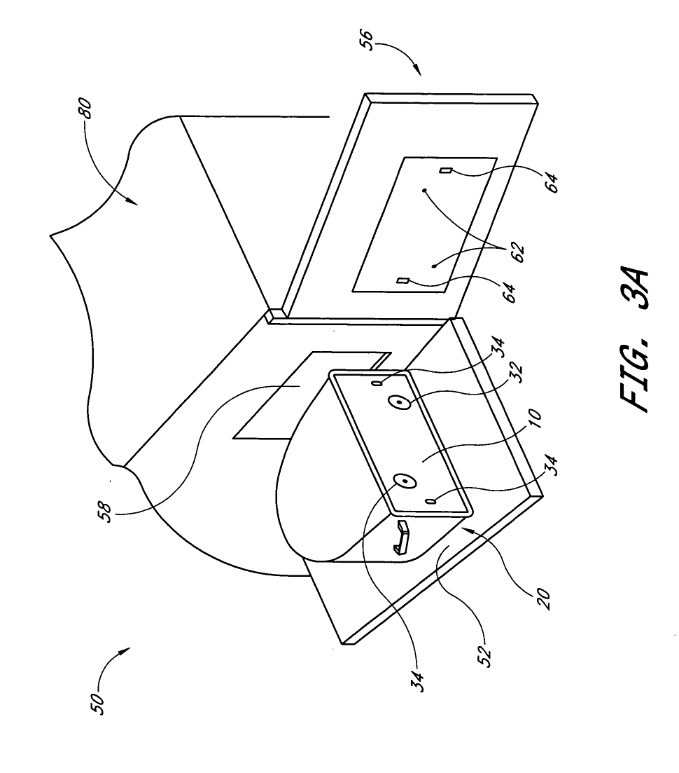

During the transport and/or storage of wafers in a semiconductor fabrication facility, the wafers are contained inside a front-opening unified pod (FOUP) carrier 20, as shown in FIG. 1 with the door removed, and in FIG. 2 with the door 10 attached. The FOUP 20 includes top 11, bottom 12, side 13, and rear walls 14, spaced shelves 26 for holding wafers, and the door for sealing the FOUP 20 during transport. Typically, the FOUP isolates the wafers from ambient particulate and molecular contamination, while also providing accurate wafer positioning. The Semiconductor Equipment Materials International Standards Program (document SEMI E47.1 incorporated herein by reference and made a part of the present disclosure) describes specifications for boxes and pods used to transport and store wafers. Additionally, a Front Opening Interface Mechanical Standard is provided in SEMI E62-0997 which is also incorporated herein by reference and made a part of the present disclosure.

The exterior of the FOUP 20 may also be fitted with a handle 22 for transporting the FOUP 20 manually. Inside, the wafers 24 are held spaced apart in a stack and are supported by ledges 26 forming slots. The top 11 of the FOUP has a handling flange 28 that can be engaged by a robot (not shown) to move the FOUP 20. A sealing mechanism 30 that is designed to press against and seal to a surface of a loading port at a process tool is located at the front opening of the FOUP. On the bottom 12 of the FOUP a coupling plate can be provided with recessed pockets or other features to facilitate in self-locating placement of the FOUP 20.

FIG. 2 shows a front side of a FOUP 20 sealed by a removable door 10. As shown, a FOUP door 10 typically has a pair of registration pins 32 for locating a door-opening mechanism. The door 10 also comprises a pair of key slots 34 in mechanical communication with a pair of latch keys on an inner side of the FOUP door 10. The latch keys are generally configured to lock or unlock the FOUP door 10 from the FOUP 20 by rotation of the key slots. The FOUP door may also include features for aligning 32 an opening mechanism with the FOUP door. Such alignment features may include registration pins, holes, slots, or any other appropriate alignment structures.

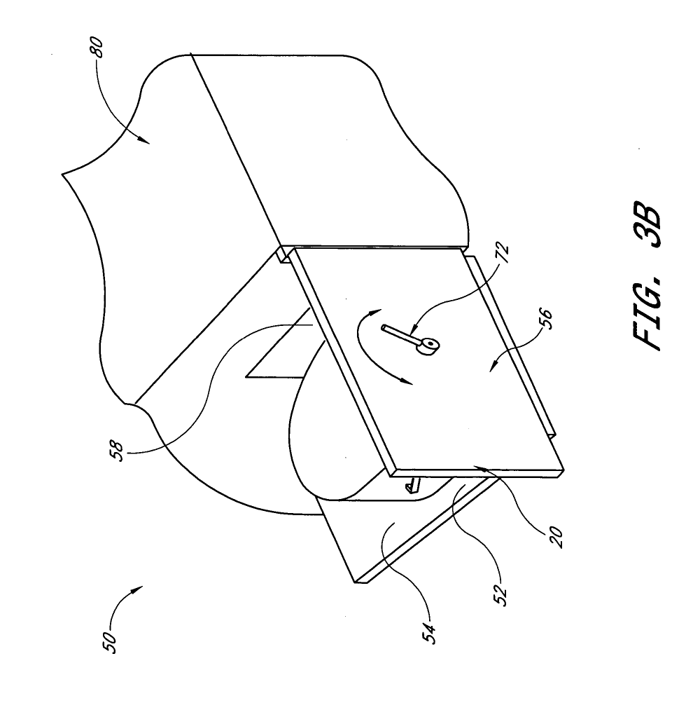

FIG. 3 illustrates a load port 50 for loading a FOUP 20 to a transfer robot 80. The load port 50 of FIG. 3 generally comprises a platform 52 which can include mechanisms for moving the FOUP linearly or rotationally on the platform 52. A manual door removal mechanism 56 is mounted to the load port platform 52. The door removal mechanism 56 generally includes features 57 for aligning with a door 10 of a FOUP, and for removing the FOUP door 10. The door removal mechanism 56 may be hinged to rotate about a vertical or horizontal axis relative to the platform 52 as desired. Alternatively, the door removal mechanism 56 may be removably or substantially rigidly mounted to the platform, allowing a FOUP to be aligned with the mechanism 56 in order to allow the FOUP door 10 to be removed.

The manual FOUP door removal device 56 generally includes pins or holes 62 for aligning the mechanism 57 with the registration pins or holes 32 of the FOUP door 10, and keys 64 for engaging and rotating the key slots 34. In embodiments in which the door removal device 56 is hinged relative to the platform, the FOUP should be placed in a position such that the keys 64, slots 34 and alignment features 32, 62 are aligned when the door removal device 56 is rotated to the position shown in FIG. 3B. In embodiments in which the door removal device 56 is rigidly mounted to the platform, the FOUP is preferably positioned on the platform such that the keys 64, slots 34, and alignment structures 32, 62 are aligned and engaged.

The FOUP door removal device 56 may be provided with an actuating mechanism 72 (see FIG. 3B) which may be actuated by a user in order to rotate the keys 64 and disengage the door 10 from the FOUP 20. The actuating mechanism of FIG. 3B is shown as a lever, however the actuating mechanism may be any appropriate device such as a wheel, slider, toggle switch, etc.

The door removal device 56 is preferably configured such that the door will be held by the device 56 as the FOUP is moved away from the device 56. Once the FOUP door 10 has been removed by the mechanism 56, the FOUP can be moved to seal against the load port opening in order to transfer wafers into and/or out of the FOUP 20. Once the transfer process is complete, the FOUP may be moved to a position in which the FOUP door can be replaced. The door 10 can be replaced by pressing the FOUP up against the door 10 which is held by the door removal device 56, and the keys may be rotated to engage the latch keys with the FOUP 20.

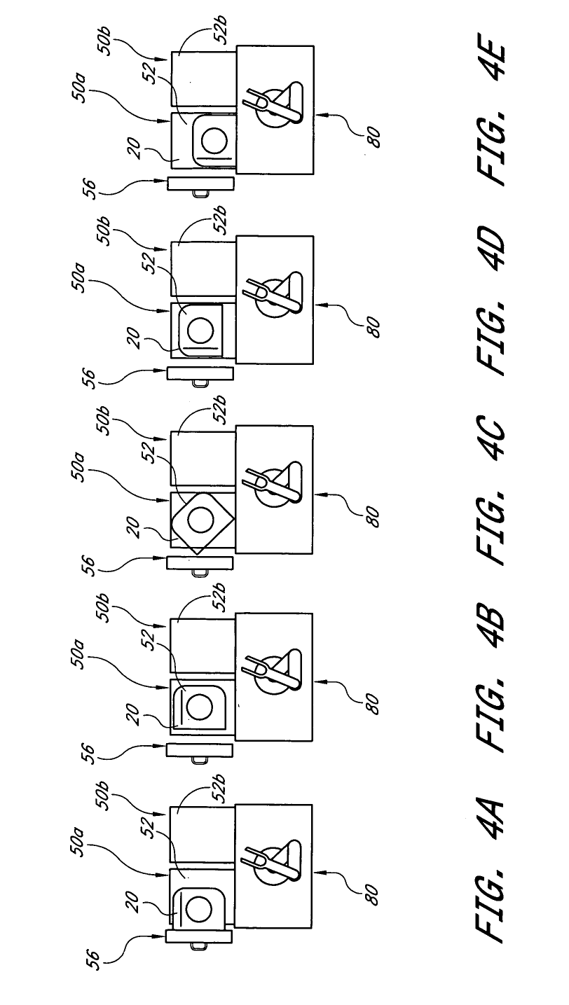

In the embodiment shown, the door removal mechanism 56 is mounted to the platform 52 such that the mechanism 56 is perpendicular to the load port opening 58. Thus the platform 52 is also configured to allow a FOUP placed thereon to be moved to be sealed against the load port opening 58. Any appropriate path between a FOUP door removal position and a wafer loading position can be used. One exemplary path of a FOUP on a platform 52 is schematically illustrated in FIGS. 4A-4E.

In FIG. 4A a FOUP 20 is shown on the platform 52 in a first position in which the FOUP door 10 is sealed against the door removal mechanism 56. The door removal mechanism 56 is operated to remove the FOUP door 10 as described above, and the FOUP 20 is translated away from the mechanism 56 to the position shown in FIG. 4B. The FOUP 20 is then rotated as shown in FIG. 4C to a position such that the FOUP 20 opening is parallel to the load port opening 82 as shown in FIG. 4D. The FOUP 20 is then translated toward the load port opening 82 until the FOUP 20 is sealed against the load port as shown in FIG. 4E.

A second FOUP 20 may be loaded and sealed to the second side of the load port 50b in a similar manner. Alternatively, any other wafer-carrying container may be positioned on the second side of the load port 50b. Wafers may then be transferred between the FOUPs (or other containers) positioned on the first and second load port sides 50a & 50b as desired. Once the desired wafer transfer process is complete, the FOUP 20 may be moved to the mechanism 56 by reversing the steps discussed above with reference to FIGS. 4A-E. The FOUP door may be manually sealed to the FOUP 20, the FOUP may be moved back away from the FOUP door opening mechanism, and the FOUP 20 may be removed from the platform 52.

The load port platform 52 may be configured to include tracks for guiding the motion of the FOUP 20 along the above-described path. The FOUP 20 may be moved along the tracks manually or automatically. Alternatively, a manual or automatic mechanism may be provided to engage the handling flange 28 on the top of the FOUP 20 in order to move the FOUP 20 along the desired path.

In the embodiment shown in FIGS. 4A-E, the load ports 50a and 50b are arranged in a side-by-side manner. Those skilled in the art will recognize that the load ports 50a and 50b may be configured such that one of the load port platforms is vertically above the other and the transfer robot 80 may be configured to transfer wafers between the vertically displaced FOUPs.

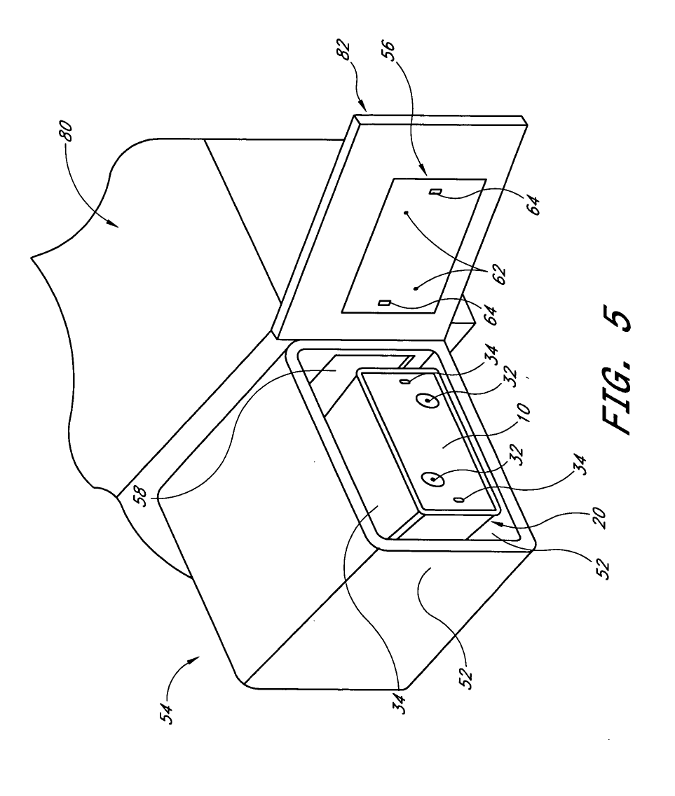

In an alternative embodiment, illustrated in FIG. 5, the platform 52 may be enclosed by a housing 50 which is sealable by a door 82. The door removal mechanism 56 may then be incorporated into the door of the housing such that a FOUP door 10 may be aligned with the FOUP door removal features 57 by closing the housing door. The load port platform housing 50 can be generally constructed such that the atmosphere within the housing may be purged with a purge gas. According to this embodiment, the wafers within a FOUP will only be exposed to a controlled environment between the time when the FOUP door is removed, and the FOUP is joined to the load port. To this end, the load port door 82 can be configured to seal the opening to the platform housing 54, and the space within the housing can be in fluid communication with the space within the transfer robot 80 such that the atmosphere between the two may be consistently maintained.

According to the embodiment of FIG. 5, a FOUP may be placed inside the housing on the platform 52 in a position such that the keys 64 mounted to the door 82 will align with the slots 34 of the FOUP door 10. The housing door 82 can then be closed, thus engaging the keys 64 within the slots 34 of the FOUP door 10. The manual lever can then be actuated to remove the FOUP door 10, and the FOUP 20 can be moved to be sealed against the opening of the load port 58 in order to allow wafers to be transferred therethrough.

Although certain preferred embodiments and examples have been described herein, it will be understood by those skilled in the art that the present inventive subject matter extends beyond the specifically disclosed embodiments to other alternative embodiments and/or uses of the invention and obvious modifications and equivalents thereof. Thus, it is intended that the scope of the present inventive subject matter herein disclosed should not be limited by the particular disclosed embodiments described above, but should be determined only by a fair reading of the claims that follow.

1. A method of transferring semiconductor wafers from a first container to a second container, said method comprising:
providing first and second containers, at least one of the containers having a plurality of wafers removably supported therein;
providing a wafer transfer robot having at least one load port, the at least one load port being configured to allow at least one of the containers to translate linearly, and to rotate thereon;
providing a door removal mechanism adapted to engage with doors of the containers;
placing the first container on the at least one load port;
engaging the door removal mechanism with a door of the first container;
manually removing the door of the first container using the door removal mechanism;
rotating the first container such that an opening in the container is in a position to allow the robot to transfer wafers through the opening; and
sealably locking the container to the opening in the load port such that wafers may be transferred through the opening.

2. The method of claim 1, wherein each container has a removable door.

3. The method of claim 2, wherein the first container is a FOUP.

4. The method of claim 3, wherein the second container is a FOUP.

5. An apparatus for transferring wafers between a first container and a second container, the apparatus comprising:
first and second supports for supporting the first and second containers, at least one of the supports being configured to allow a container to be rotatable and linearly translatable thereon;
a mechanism for manually removing a door of at least one of the first and second containers, the mechanism being mounted in proximity to at least one of the platforms; and
a wafer-transfer robot configured to transfer wafers in a controlled environment between the first and second containers.

6. The apparatus of claim 5, further comprising a second mechanism for manually removing a door of a remaining one of the first and second containers.

7. The apparatus of claim 5, wherein the mechanism is mounted to the apparatus.

8. The apparatus of claim 5, wherein the first container is a FOUP.

9. The apparatus of claim 8, wherein the second container is a FOUP.

10. The apparatus of claim 8, wherein the second container is a removable cassette.

11. The apparatus of claim 8, wherein the second container is a shipping box.

12. A method of transferring wafers from a first container to a second container, said method comprising:
providing first and second containers, each container having a removable door, at least one of the containers having a plurality of wafers removably supported therein;
providing a wafer transfer robot;
providing at least one load port with a platform, the platform being configured to allow at least one of the containers to translate linearly and to rotate thereon, the platform being enclosed by a housing;
providing a mechanism for manually removing a door of a container, the mechanism being integral with a door to the housing;
placing a first container on the at least one platform;
closing the housing door, thereby sealing the first container inside the housing;
employing the mechanism to manually remove the door of the first container;
linearly displacing the container away from the housing door;
rotating the first container such that a front surface of the container is parallel to an opening in the load port;
linearly displacing the container toward the load port opening;
sealably locking the container to the opening in the load port such that wafers may be transferred through the opening; and
exchanging wafers between the first and second containers.
